(19) United States
(12) Patent Application Publication
(10) Pub. No.: US 2003/0033972 A1
(43) Pub. Date: Feb. 20, 2003

(54) Controlled crown growth process for czochralski single crystal silicon

(75) Inventor: Massoud Javidi, St. Peters, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/215,113

(22) Filed: Aug. 8, 2002

Related U.S. Application Data
(60) Provisional application No. 60/312,573, filed on Aug. 15, 2001.

(51) Int. Cl. C30B 15/00; C30B 21/06; C30B 27/02; C30B 28/10; C30B 30/04

(52) U.S. Cl. 117/13

(57) ABSTRACT

The present invention relates to a process for preparing a single crystal silicon ingot wherein controlled growth of the crown or taper is used to establish a desired vacancy-interstitial boundary position in the main body of the ingot early in the growth process, such that the overall yield of the desired type of silicon is increased. Controlled growth is achieved in a first embodiment by actually increasing the pull rate during growth of the crown or taper, prior to the roll or growth of the shoulder of the ingot.

### CROSS-REFERENCE TO RELATED APPLICATION

This application claims the benefit of U.S. Provisional Application Serial No. 60/312,573, filed Aug. 15, 2001, the entire content of which is incorporated herein by reference.

### BACKGROUND OF THE INVENTION

The present invention generally relates to the preparation of semiconductor grade single crystal silicon which is used in the manufacture of electronic components. More particularly, the present invention relates to a process for preparing a single crystal silicon ingot wherein controlled growth of the crown or taper is used to establish a desired vacancy-interstitial boundary position in the main body of the ingot much earlier in the growth process, such that the overall yield of the desired type of silicon is increased.

Single crystal silicon, which is the starting material for most processes for the fabrication of semiconductor electronic components, is commonly prepared by the so-called Czochralski (“Cz”) method. Referring now to FIG. 1, in this method polycrystalline silicon (“polysilicon”) is charged to a crucible and melted, a seed crystal (SC) is brought into contact with the molten silicon and a single crystal is grown by slow extraction. After formation of a neck (N) is complete, the diameter of the crystal is enlarged, typically by decreasing the pulling rate and/or the melt temperature, to form a crown or taper section (C/T), also referred to in some instances as the seed-cone, until the desired or target diameter is reached. Once the target diameter is reached, formation of the shoulder (Sh) occurs, the taper being “rolled” to begin growth of the constant diameter portion (CD), or cylindrical main body, of the crystal by increasing the pull rate. The main body of the crystal has an approximately constant diameter and is grown by controlling the pull rate and the melt temperature while compensating for the decreasing melt level. Near the end of the growth process but before the crucible is emptied of molten silicon, the crystal diameter is typically reduced gradually to form an end opposite the taper, commonly referred to as the end-cone. The end-cone is typically formed by increasing the crystal pull rate and heat supplied to the crucible. When the diameter becomes small enough, the crystal is then separated from the melt.

The type and initial concentration of intrinsic point defects in the single crystal silicon (i.e., silicon lattice vacancies or silicon self-interstitials) are determined as the ingot cools from the temperature of solidification (i.e., about 1414° C.) to a temperature greater than about 1300° C.; that is, the type and initial concentration of these defects are controlled by the ratio v/G₀, where v is the growth velocity and G₀ is the average axial temperature gradient over this temperature range. Referring now to FIG. 2, for increasing values of v/G₀, a transition from decreasingly self-interstitial dominated growth to increasingly vacancy dominated growth occurs near a critical value of v/G₀ which, based upon currently available information, appears to be about 2.1×10⁻⁵ cm²/sK, where G₀ is determined under conditions in which the axial temperature gradient is constant within the temperature range defined above.

Given that G₀ typically varies along the radius of the main body of the crystal at a given axial position (G₀ typically increasing from the central axis toward the lateral surface of the main body of the ingot), a transition in the silicon often occurs from vacancy dominated to self-interstitial dominated, particularly near the crown or taper, resulting in the presence of a vacancy-interstitial (“V/I”) boundary (a core region of vacancy dominated material surrounded by an outer region of interstitial dominated material). Furthermore, because the crown or taper has heretofore been grown without consideration being given to the desired type of silicon in the main body of the crystal, the focus rather being on the shape of the taper needed in order to achieve the desired diameter of the main body of the crystal, some initial segment of the main body is typically not suitable for its intended purpose. This is particularly the case when an interstitial dominated region of some substantial radial width is desired, because the V/I boundary is typically close to the lateral surface due to the high pull rates employed at the roll during shoulder formation. In conventional processes, the growth velocity is then decreased until the target value is reached, resulting in the inward movement of the V/I boundary along the axial length of the crystal. Similarly, even if the crystal is to be vacancy dominated from the center of the crystal to the lateral surface, this is difficult to achieve because the rapid increase in pull rate at the roll is generally not sufficient to move the V/I boundary to the lateral surface, due to the slow pull rate employed to achieve the desired taper shape.

Accordingly, a need continues to exist for a process for preparing single crystal silicon wherein the taper or crown section of the crystal is grown in a way which not only enables the desired shape to be obtained (i.e., one which provides both zero-dislocation growth and low cycle time), but which also enables the desired growth conditions for the main body of the ingot to be established at or before the roll occurs, such that the desired type of single crystal silicon material is formed as soon as growth of the main body of the ingot begins. In this way, the yield of the desired material from the crystal can be increased.

### SUMMARY OF THE INVENTION

Among the features of the present invention, therefore, is the provision of a single crystal silicon ingot, and a process for the preparation thereof, wherein an initial segment the main body or constant diameter portion of the ingot near the taper contains an axially symmetric region of interstitial dominated material of a substantial radial width; the provision of such an ingot, and process for the preparation thereof, wherein the V/I boundary within the main body of the ingot has a substantially constant radial position over the axial length thereof; and, the provision of such a process wherein one or more parameters affecting taper growth, including pull rate, crucible and seed rotation rates, heater power, and/or Hr (a distance between the melt surface and a device positioned above the melt surface for controlling heat transfer at the melt/solid interface) are controlled to establish the V/I boundary at a desired position within the main body of the ingot.

Briefly, therefore, the present invention is directed to a single crystal silicon ingot having a central axis, a taper, an end opposite the taper, and a main body between the taper and the opposite end having a lateral surface and a radius R extending from the central axis to the lateral surface which is at least about 75 mm. The ingot is characterized in that, after it is grown and cooled from the solidification temperature, the main body contains a region extending radially inward from the lateral surface which is axially symmetric about the central axis wherein silicon self-interstitials are the predominant intrinsic point defect, the axially symmetric region having an average radial width, as measured from the lateral surface toward the central axis, which is at least about 0.3R within about the first 10% of the main body.

The present invention is further directed to a single crystal silicon ingot having a central axis, a taper, an end opposite the taper, and a main body between the taper and the opposite end having a lateral surface and a radius R extending from the central axis to the lateral surface which is at least about 75 mm. The ingot is characterized in that, after it is grown and cooled from the solidification temperature, the main body contains a region extending radially inward from the lateral surface which is axially symmetric about the central axis wherein silicon self-interstitials are the predominant intrinsic point defect, the axially symmetric region having a radial width, as measured from the lateral surface toward the central axis, over about the first half of the main body of the ingot which varies by less than about 10%.

The present invention is still further directed to such an ingot wherein the axially symmetric, interstitial dominated region, the axially symmetric, vacancy-dominated region, or both, is(are) substantially free of agglomerated intrinsic point defects.

The present invention is still further directed to a process for preparing single crystal silicon ingots having such features.

The present invention is still further directed to a process for preparing a single crystal silicon ingot having a central axis, a crown, an end opposite the crown, and a main body between the crown and the opposite end which has a lateral surface and a radius extending from the central axis to the lateral surface which is at least about 75 mm. The process comprises (i) heating polycrystalline silicon in a crucible to form a silicon melt, (ii) contacting a seed crystal and the melt, (iii) withdrawing the seed crystal from the melt to grow a neck portion adjacent the seed crystal, (iv) growing an outwardly flaring crown adjacent the neck, (v) growing a main body adjacent the outwardly flaring crown.

In a first embodiment of this process, about the first 10% of the main body contains a region extending radially inward from the lateral surface which is axially symmetric about the central axis and having silicon self-interstitials are the predominant intrinsic point defect. The axially symmetric region has an average radial width, as measured from the lateral surface toward the central axis, which is at least about 0.3R.

In a second embodiment of this process, the main body contains a region extending radially inward from the lateral surface which is axially symmetric about the central axis and which has silicon self-interstitials as the predominant intrinsic point defect. The axially symmetric region additionally has a radial width, as measured from the lateral surface toward the central axis, over about the first half of the axial length of the main body which varies by less than about 10%.

The present invention is still further directed to a process for preparing a single crystal silicon ingot in which the ingot comprises a central axis, a crown, an end opposite the crown, and a main body between the crown and the opposite end having a lateral surface and a radius extending from the central axis to the lateral surface which is at least about 75 mm. The ingot is grown and then cooled from the solidification temperature in accordance with the Czochralski method wherein a seed crystal is lowered into contact with a silicon melt contained within a crucible and then withdrawn. The process comprises growing at least a first segment of the main body of the ingot at a substantially constant pull rate, the pull rate varying by less than about 10% over an axial length of said segment, wherein said segment (i) has an axial length which is at least about 25% of the main body axial length, and (ii) contains a region extending radially inward from the lateral surface which is axially symmetric about the central axis wherein silicon self-interstitials are the predominant intrinsic point defect.

Other objects and features of this invention will be in part apparent and in part pointed out hereinafter.

### BRIEF DESCRIPTION OF THE DRAWINGS

FIG. 1 illustrates a longitudinal, cross-sectional view of a single crystal silicon ingot, showing in detail the neck, taper and main body or constant diameter portion of the ingot.

FIG. 2 is a graph which shows an example of how the initial concentration of self-interstitials, [I], and vacancies, [V], changes with an increase in the value of the ratio v/G₀, where v is the growth rate and G₀ is the average axial temperature gradient.

FIG. 3A illustrates a longitudinal, cross-sectional view of a single crystal silicon ingot, showing in detail the V/I boundary and an interstitial dominated, axially symmetric region of a main body of the ingot.

FIG. 3B illustrates a longitudinal, cross-sectional view of a single crystal silicon ingot, showing in detail a vacancy dominated, axially symmetric region of a main body of the ingot (wherein the width of the region is substantially equal to the radius of the main body of the ingot).

FIGS. 4A through 4E are prints of digital images of disc or slug quarters, following copper decoration and a defect-delineating etch as further described herein, showing the V/I boundary positions at various axial positions from about a 300 mm (nominal diameter) single crystal silicon ingot (wherein, moving from center to edge, there can be observed (i) a vacancy dominated core wherein agglomerated vacancy defects are present, (ii) a dark, agglomerated defect free ring which is adjacent the vacancy dominated core and which contains the V/I boundary, (iii) an interstitial dominated ring adjacent the defect free ring, and (iv) another dark, agglomerated defect free ring at or near the outer edge and adjacent the interstitial dominated ring). Specifically, as measured from the crown/taper section, A was sliced about 0.5 inches therefrom, B was sliced about 5.6 inches therefrom, C was sliced about 12.7 inches therefrom, D was sliced about 16.8 inches therefrom, and E was sliced just before the tail-cone.

FIGS. 5A through 5C are prints of digital images of disc or slug quarters, following copper decoration and a defect-delineating etch as further described herein, showing fully vacancy dominated (i.e., no V/I boundary present) silicon sliced at various axial positions from about a 300 mm (nominal diameter) single crystal silicon ingot (the dark ring at the outer edge being defect free). Specifically, A was sliced about 0.5 inches from the crown/taper section, B was sliced from about the middle of the main body of the ingot, and C was sliced just before the tail-cone of the ingot.

FIGS. 6A through 6E are graphs illustrating profiles of the heater power (A), taper diameter (B), crucible rotation rate (C), pull rate (D) and seed rotation rate (E), relative to the length of the taper section, for a process wherein an axially symmetric region of interstitial dominated material of a width of at least about 0.3R is formed. (It is to be noted that, for all graphs, the base coordinate for the X, or vertical, axis denotes the conditions at the end of neck growth.)

FIGS. 7A through 7E are graphs illustrating profiles of the heater power (A), diameter (B), crucible rotation rate (C), pull rate (D) and seed rotation rate (E), relative to the length of the taper section, for a process wherein an axially symmetric region of vacancy dominated material of a width substantially equal to the width of the main body of the ingot is formed. (It is to be noted that, for all graphs, the base coordinate for the X, or vertical, axis denotes the conditions at the end of neck growth.)

FIGS. 8A and 8B are prints of digital images of (8A) axially sliced taper or crown section of an ingot (about 300 mm nominal diameter), and (8B) a slug quarter of a first segment of the main body of the ingot (just after the taper segment), prepared in accordance with the present process (e.g., the process illustrated by FIGS. 6A through 6E), following copper decoration and a defect-delineating etch as further described herein, showing the V/I boundary position (wherein, moving radially from center to edge, and near the bottom of the taper in 8A, there can be observed (i) a vacancy dominated core wherein agglomerated vacancy defects are present, (ii) an agglomerated defect free ring which is adjacent the vacancy-dominated core and which contains the V/I boundary, and, in the case of the slug, (iii) a thin, interstitial dominated ring adjacent the defect free ring, and (iv) another thin, agglomerated defect free ring at or near the outer edge and adjacent the interstitial dominated region). It is to be noted that, in FIG. 8A, the V/I boundary is clearly established within the crown/taper section at a position substantially inward of the outer edge of the ingot.

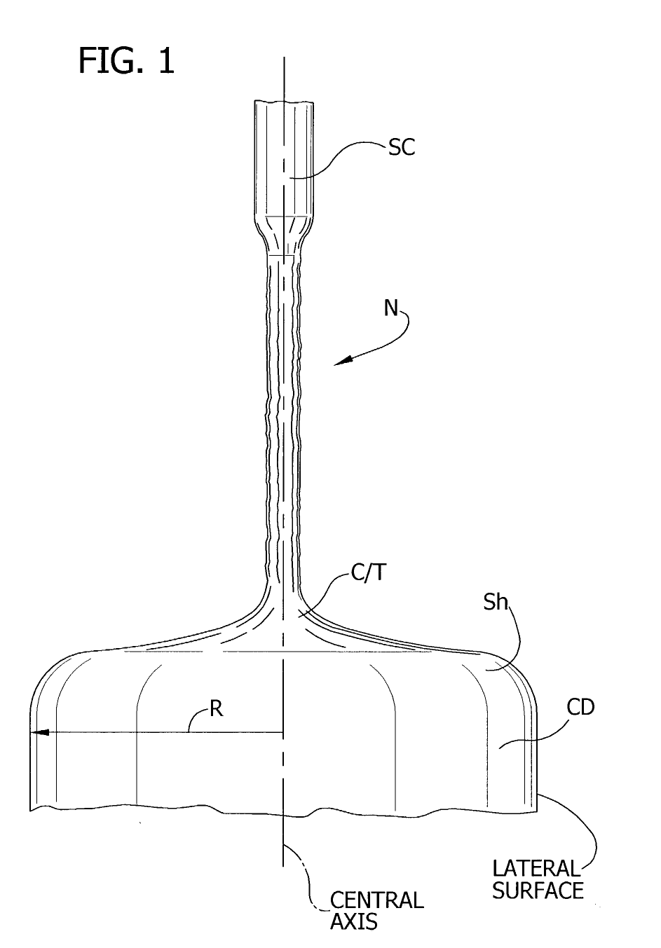

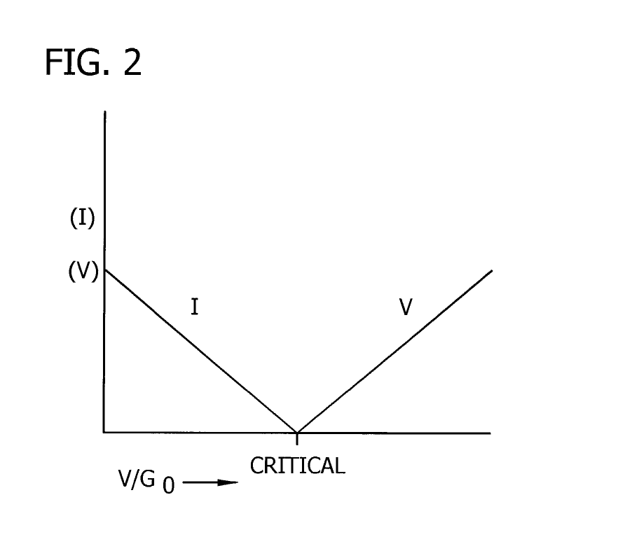

Corresponding reference characters indicate corresponding parts throughout the drawings.

### DETAILED DESCRIPTION OF THE PREFERRED EMBODIMENTS

In accordance with the present invention, it has been discovered that growth of the crown or taper section of a single crystal silicon ingot can be controlled in order to establish a vacancy-interstitial (“V/I”) boundary at a desired position at or before initiating growth of the main body or constant diameter portion of the ingot, or much earlier thereafter than has heretofore been possible. As a result, the yield of the desired silicon material (i.e., self-interstitial or vacancy dominated) is increased, while still enabling the desired crown or taper shape to be formed, such that both zero dislocation growth and shorter cycle times are achieved.

Establishment of the desired V/I boundary position in the growth process is achieved in accordance with the present invention by means of controlling one or more of the parameters affecting single crystal silicon growth, including for example growth velocity (primarily dictated by the pull rate), seed and crucible rotation rates, heater power and/or Hr (i.e., the distance between the surface of the silicon melt and a device for controlling heat transfer at the melt/solid interface positioned above the melt surface).

Single Crystal Silicon Ingot

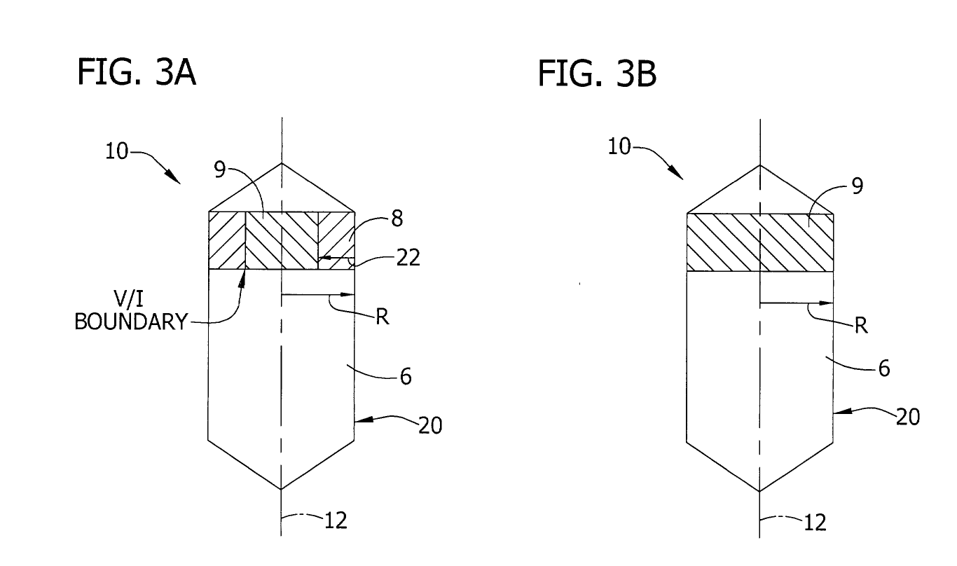

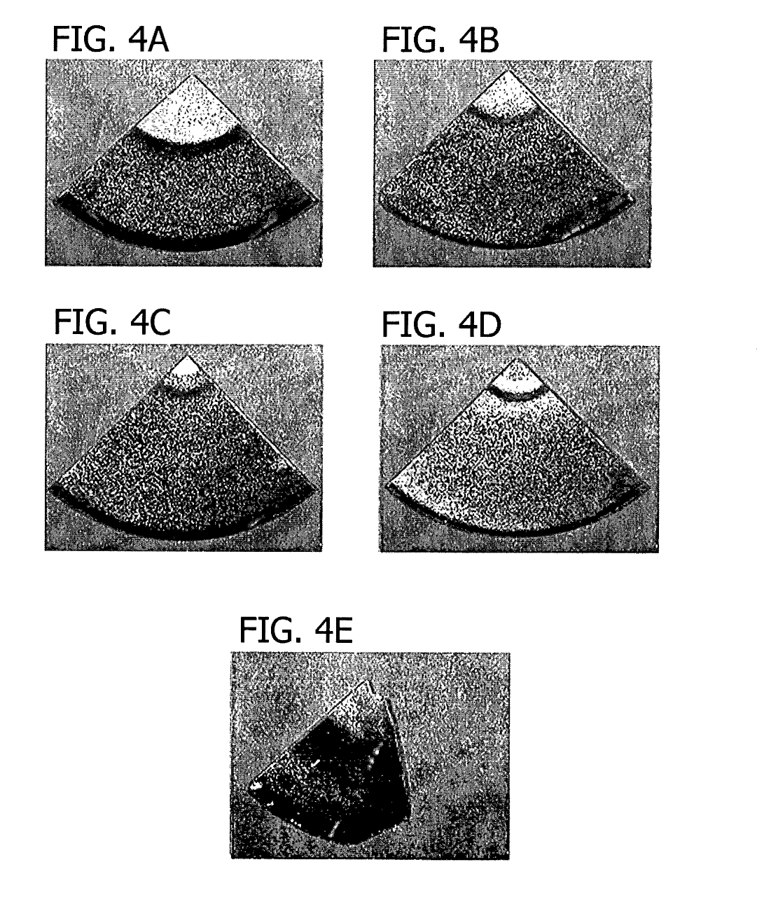

The process of the present invention enables the V/I boundary to be established in the main body or constant diameter portion of the ingot at a much earlier stage in the growth process, as compared to conventional processes, thus increasing yield of the desired silicon material. More specifically, referring now to FIG. 3A, as well as FIGS. 4A through 4E, the present invention enables the preparation of a single crystal silicon ingot 10 having a nominal radius, R, of at least about 75 mm (e.g., about 100 mm, 150 mm or more) which, after it has been grown and cooled from the solidification temperature, is characterized by the main body 6 containing a region 8 extending radially inward from the lateral surface 20 which is axially symmetric about the central axis 12 wherein silicon self-interstitials are the predominant intrinsic point defect. This axially symmetric region has an average radial width 22, as measured from the lateral surface toward the central axis, within about the first 10% of the main body of the ingot or less (e.g., about the first 8%, 6%, 4% or 2%) which is at least about 0.3R (e.g., about 0.4R, 0.5R, 0.6R, 0.7R, 0.8R, 0.9R or even 1R). In one preferred embodiment, the desired radial width of this axially symmetric region is established at the time growth of the main body begins; that is, the desired V/I boundary position is established at the roll, or within the shoulder portion of the ingot.

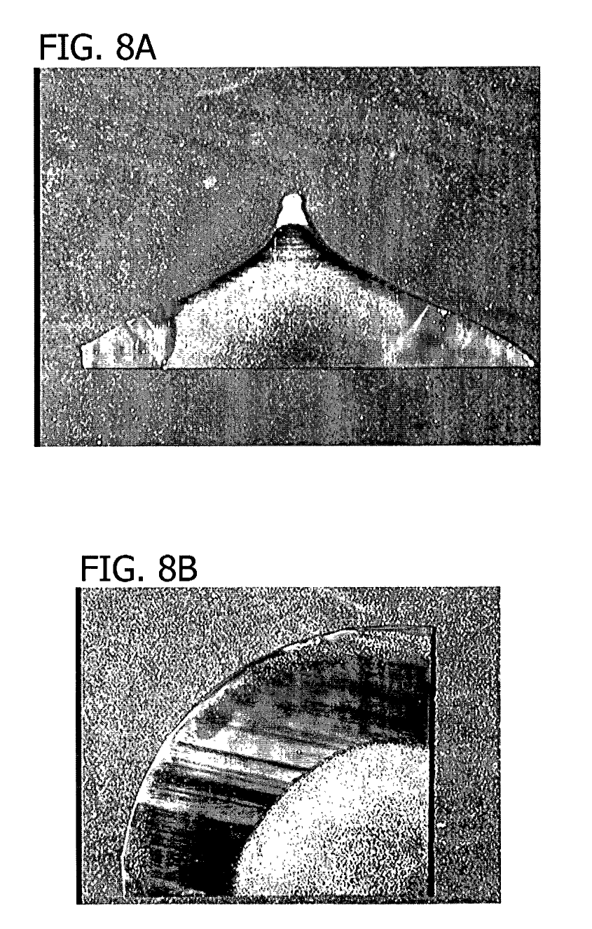

Referring now to FIGS. 8A and 8B, because the process of the present invention enables the V/I boundary to be established at the desired position very early in the main body of the ingot (see, e.g., FIG. 8A, wherein the V/I boundary position is established in the taper), variations in the V/I boundary position can be minimized. More specifically, because the desired growth conditions for the main body of the ingot can be established earlier in the growth process (e.g., during formation of the taper or shoulder), the desired type of material, having the desired radial width, can be grown much earlier within the main body of the ingot. Accordingly, the main body of the ingot can be prepared to contain an axially symmetric region wherein silicon self-interstitials are the predominant intrinsic point defect and which has a radial width, as measured from the lateral surface toward the central axis, over a substantial segment of the main body of the ingot (e.g., about the first 15%, 25%, 35%, 45%, 50% or more) which is substantially constant, varying by less than about 10% (e.g., less than about 8%, 6%, 4%, 2% or even 1%). Stated another way, because the desired growth conditions are established at the outset of the growth of the main body of the ingot, the V/I boundary remains substantially constant over a substantial axial length (as measured from the beginning of the main body of the ingot).

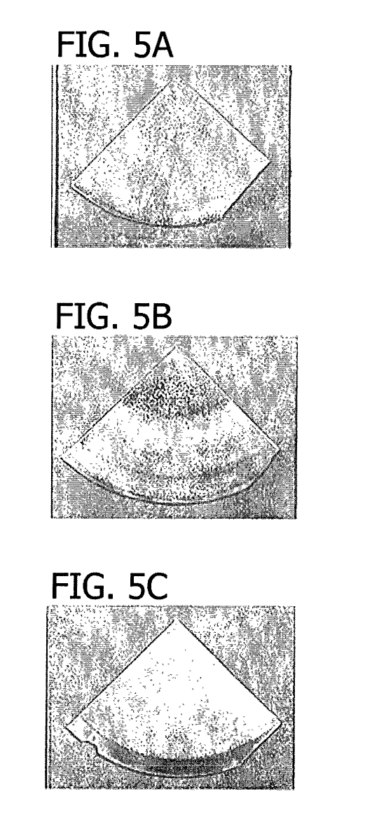

Additionally, it is to be noted that the present process can be controlled to maximize the vacancy-dominated region, also. For example, referring now to FIG. 3B, as well as FIGS. 5A through 5C, using the same or similar hot zone (i.e., without changing the thermal conditions within the hot zone), the same growth parameters can be controlled/altered to achieve an axially symmetric region 9 of vacancy dominated material, which preferably extends from the central axis to the lateral surface at the time growth of the main body of the ingot is initiated. Stated another way, these same parameters can be controlled to essentially move the V/I boundary to the lateral surface by the time the roll is complete, such that the main body is entirely vacancy dominated from the central axis to the lateral surface (excluding, for example, surface diffusion effects which in some cases might alter the type of silicon material at the surface).

Growth Conditions

Generally speaking, formation of the crown or taper of the single crystal silicon ingot has heretofore been achieved using the same or similar approach, with the same or similar considerations in mind, regardless of the type of silicon material (e.g., vacancy or interstitial dominated) to be formed. More specifically, to-date taper growth has typically been achieved by controlling the crucible rotation rate and heater power, and to a lesser extent the pull rate (the pull rate typically being maintained at a constant value which is less than that employed during neck growth), in order to reach the desired shape and diameter, before initiation of substantially constant diameter growth (the pull rate typically being increased at the shoulder to “roll” the ingot and initiate formation of the main body, resulting in the formation or expansion of a vacancy-dominated region within the ingot, the pull rate then being reduced exponentially until the desired pull rate for main body growth is achieved).

It is to be noted, however, that the same parameters which are used to control the macroscopic properties (e.g., shape and diameter) of the taper also impact the microscopic properties (e.g., the type of intrinsic point defects present), the pull rate affecting growth velocity while heater power, rotation rates (crucible and seed), etc. affect the average axial temperature gradient. Because the macroscopic and microscopic properties are coupled, if consideration is given only to diameter requirements during the taper growth process, quality can and typically does suffer.

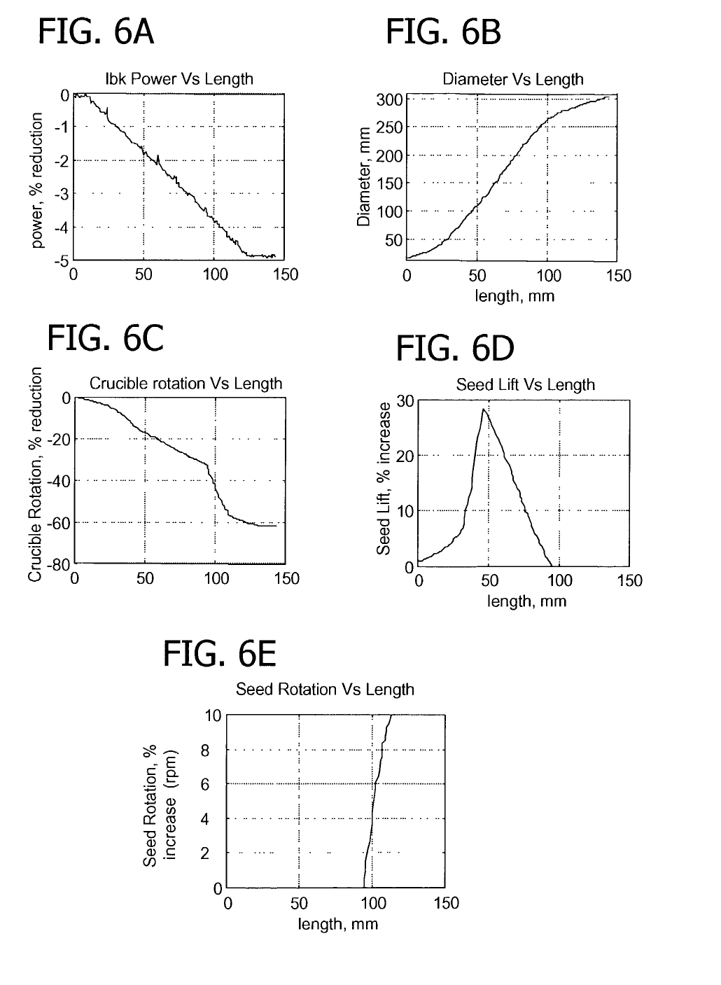

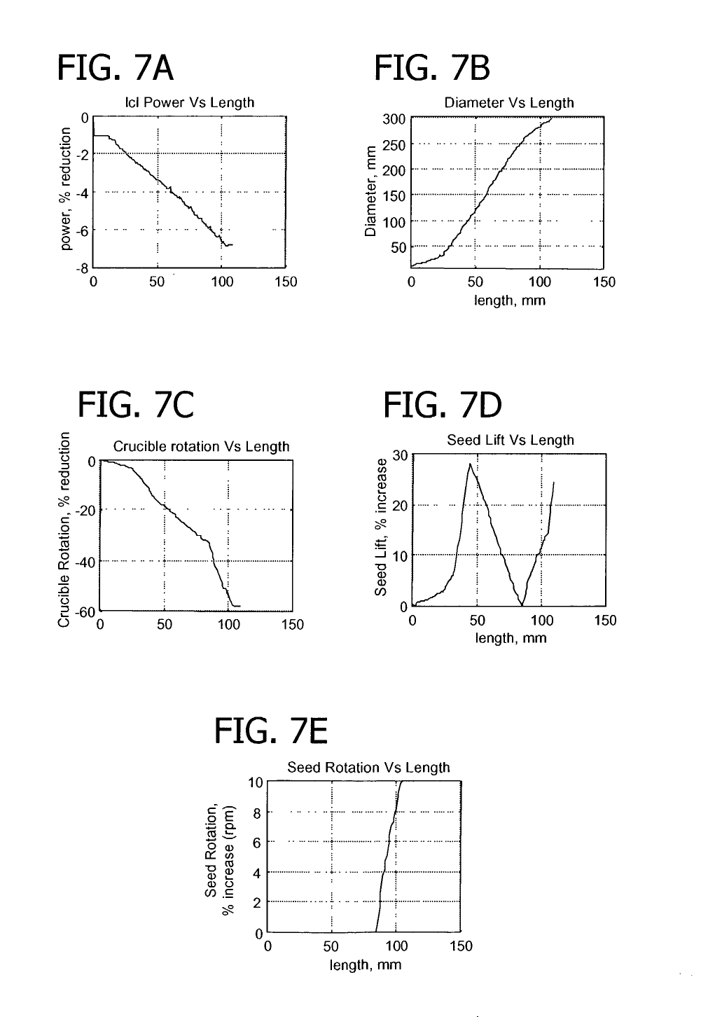

In contrast to conventional processes, in accordance with the present invention, these growth parameters, and optionally others, are controlled not only with diameter or shape in mind (such that zero-dislocation growth and shorter cycle times are achieved), but also the type of silicon to be grown (e.g., self-interstitial or vacancy dominated), in order to maximize yield or throughput of the desired silicon material. In a first embodiment, the pull rate is controlled (i.e., increased/decreased) in order to maintain substantially the same slope for the growth diameter (see, e.g., FIGS. 6B and 7B) for the midsection of the taper, while at the same time ensuring that the target or desired growth rate for the main body of the ingot is achieved at or before main body growth is initiated. More specifically, in a first embodiment, upon completion of the formation of the neck, the pull rate is increased for a period of time, relative to the pull rate upon completion of the neck, while other parameters (e.g., crucible and/or seed rotation rates, heater power, etc.) are utilized to achieve an increase in diameter of the taper (an increase in pull rate typically resulting in a decrease in diameter, all other things being equal). Referring now to FIGS. 6A through 6E, for a single crystal silicon ingot wherein an interstitial dominated, axially symmetric region is present in the main body (as described above), the pull rate (FIG. 6D) is typically increased by at least about 10%, 20%, 30% or more, relative to the pull rate upon completion of the neck segment of the ingot, during formation of about the first 25% to 35% of the taper, after which the rate is decreased, for example in a generally linear manner, over the next segment of the taper (e.g., about the next 25%, 30%, 35% or more), until the desired pull rate for the main body of the ingot is reached. In order to achieve an increase in diameter (FIG. 6B) as the pull rate is increased, and still allow for a reduction in crucible rotation rate (FIG. 6C) so that the desired oxygen content of the ingot can be achieved, the heater power (FIG. 6A) is reduced. More specifically, as the pull rate profile is changing, power supplied to the side and/or bottom heaters are typically reduced, in for example a generally linear manner, by less than about 10% over a substantial portion of the length of the taper (e.g., about 75%, 80%, 85%); that is, the power is reduced by about 10%, 8%, 6% or less over a substantial portion of the taper length (e.g., about 100 mm, 125 mm or more), at which point the power level remains essentially constant for the remainder of the taper growth.

Typically, at substantially the same time the pull rate is increased, the crucible rotation rate is decreased by about 25%, 30%, 35% or more, in for example a generally linear manner, over about the first 40%, 50%, 60% or more of the taper length while seed rotation (6E) remains generally constant, all relative to the corresponding rotation rates at the time neck growth ceases. After this portion of the taper has been grown, a more rapid decrease (e.g., about 15%, 20%, 25% or more) in crucible rotation occurs over the next about 10%, 15%, 20%, 25% or more of the taper, while at the same time a rapid increase in seed rotation rate occurs (e.g., increase of about 5%, 10% or more). Both the seed and crucible rotation rates then remain substantially constant during growth of the remainder of the taper (e.g., about the last 10%, 15% or 20%).

A similar approach may be employed for a process wherein an axially symmetric region of vacancy dominated material, of a substantial radial width, extending radially outward from the central axis is to be formed. More specifically, these same growth parameters may also be controlled in a manner which enables a vacancy-dominated region which extends from the central axis to the lateral surface of the main body of the ingot to be formed, essentially as soon as growth of the main body is initiated (e.g., within about the first 5%, 3%, 1%, 0.5% or less of main body growth). Referring now to FIGS. 7A through 7E, in this approach the pull rate is also increased after the neck growth is complete, in a manner substantially the same as that employed with an axially symmetric, interstitial dominated region is to be formed (as described above); that is, the pull rate (FIG. 7D) is typically increased by at least about 10%, 20%, 30% or more, relative to the pull rate upon completion of the neck segment of the ingot, during formation of about the first 25% to 35% of the taper, after which the rate is decreased, for example in a generally linear manner, over the next segment of the taper (e.g., about the next 25%, 30%, 35% or more), to a rate substantially similar to the rate at the end of neck growth. However, unlike the approach wherein an interstitial dominated region is to be formed, in the present approach the rate is again increased prior to initiation of shoulder growth. Typically, for this second increase, the degree to which the rate is increased is equal to or less than the degree of the first increase (e.g., about 70%, 80%, 90% of the first increase).

As previously noted, in order to achieve an increase in diameter (FIG. 7B) as the pull rate is increased, and still allow for a reduction in crucible rotation rate (FIG. 7C) so that the desired oxygen content of the ingot can be achieved, the heater power (FIG. 7A) is typically reduced. More specifically, as the pull rate profile is changing, power supplied to the side and/or bottom heaters is typically reduced, for example in a generally linear manner, by less than about 15% over a substantial portion of the length of the taper (e.g., about 75%, 80%, 85%); that is, the power is reduced by about 10%, 8% or 6% over a substantial portion of the taper length (e.g., about 75 mm, 100 mm or more), at which point the power level remains essentially constant for the remainder of the taper growth.

In this regard it is to be noted that the total reduction in power during taper growth is generally a function of the final body section diameter and the desired pull rate. In contrast, point defect concentration and morphology are generally a function of pull rate and thermal gradient(s), the thermal gradient(s) in turn being a function of the hotzone design/composition.

Typically, at substantially the same time the pull rate is increased, the crucible rotation rate is decreased by about 25%, 30%, 35% or more, in for example a generally linear manner, over about the first 50%, 60%, 70% or more of the taper length while seed rotation (7E) generally remains constant, all relative to the rotation rates at the time neck growth ceases. After this portion of the taper has been grown, a more rapid decrease (e.g., about 10%, 15%, 20%, 25% or more) in crucible rotation occurs over the next about 10%, 15%, 20%, 25% or more of the taper, while at the same time a rapid increase in seed rotation rate occurs (e.g., increase of about 5%, 10% or more). Both the seed and crucible rotation rates then remain substantially constant during growth of the remainder of the taper (e.g., about the last 5%, 10%, or 15%).

In view of the foregoing, it can be seen that, by increasing the pull rate during taper growth once neck growth is complete, the taper can be formed in a way which allows not only the desired oxygen content to be established within the initial stages of the main body of the ingot, but also the desired type of material. However, in this regard it is to be noted that, generally speaking, the thermal conditions from one crystal puller to the next may vary, and further that the thermal conditions within the same puller can change over time. Accordingly, the degree and timing of the change in these parameters needed to achieve the desired result may be other than herein described without departing from the scope of the present invention. For example, from one puller to the next, or within the same puller over time, modeling or empirical experimentation may be needed to optimize the control parameters of the present process.

It is to be further noted that, in addition to utilizing an increase in pull rate during taper growth, in an alternative embodiment a more convention pull rate profile may be used (e.g., wherein the pull rate remains substantially constant, at some value less than that employed during neck growth, or alternatively decreases after neck growth, until roll occurs) in conjunction with different crucible/seed rotation rate profiles and/or heater profiles.

It is to be still further noted that the above-described embodiments are preferably carried out in a hot zone wherein a device for controlling heat transfer at the melt/solid interface is positioned above the melt surface (e.g., a reflector, radiation shield, purge tube, light pipe, etc.), and further that the distance (i.e., “Hr”) between the melt surface and this device remains substantially constant throughout the taper growth process. However, in an alternative embodiment, this distance Hr may be adjusted using means known in the art during taper growth to achieve the results of the present invention.

It is to be still further noted that, with respect to Hr for example, the present invention enables ingots to be grown without changing the thermal conditions within the crystal puller. For example, a full vacancy or interstitial dominated region (i.e., center to lateral surface) can be formed without changing the thermal conditions (e.g., Hr) within a given crystal puller (such as a 300 mm Kayex Crystal Grower).

Related Processes

The present process may be employed in both open hot zones and closed hot zones (i.e., hot zones designed to slowly cool the solidified ingot, at rates such as those described in, for example, U.S. Pat. Nos. 6,254,672 and 5,919,302). In one preferred embodiment, the present process is employed to increase the yield of single crystal silicon material that is substantially free of agglomerated intrinsic point defects (e.g., defects commonly referred to as A-defects or B-defects, which are self-interstitial agglomerated defects, or D-defects, which are vacancy defects). (See, e.g., U.S. Pat. Nos. 6,287,380, 6,254,672 and 5,919,302, all of which are incorporated herein by reference.) Stated another way, the present process can be employed to prepare a vacancy or interstitial dominated region, or both, which is substantially free of agglomerated intrinsic point defects (including in some embodiments B-defects).

Additionally, one or more features of the present process may be automated by means common in the art, including for example (i) control of Hr (see, e.g., U.S. Pat. No. 6,171,391, which is incorporated herein by reference and which describes a vision system/method for measuring the melt level/position inside the crystal pulling apparatus during ingot growth relative to, for example, a reflector positioned above the melt), and (ii) control of one or more process parameters (e.g., pull rate, rotation rates, heater power, etc.) during taper growth (see, e.g., U.S. Pat. Nos. 6,241,818 and 6,203,611, which are incorporated herein by reference).

It is to be noted that the present invention is advantageous in that, when used for example in a growth process wherein a cusp magnetic field is employed, elimination of corkscrew effects can be eliminated in the initial segments of the main body of the ingot.

It is to be further noted that the present process may be employed to prepare, for example, P, P+ and N type single crystal silicon ingots (the growth conditions as described herein being adjusted accordingly in view of the impact a given dopant type and/or dopant concentration may have on the desired position of the V/I boundary in the crown/taper section, as generally understood in the art).

Detection Methods

Agglomerated defects may be detected by a number of different techniques. For example, flow pattern defects, or D-defects, are typically detected by preferentially etching the single crystal silicon sample in a Secco etch solution for about 30 minutes, and then subjecting the sample to microscopic inspection. (See, e.g., H. Yamagishi et al., Semicond. Sci. Technol. 7, A135 (1992), which is incorporated herein by reference.) Although standard for the detection of agglomerated vacancy defects, this process may also be used to detect A-defects. When this technique is used, such defects appear as large pits on the surface of the sample when present.

Additionally, agglomerated intrinsic point defects may be visually detected by decorating these defects with a metal capable of diffusing into the single crystal silicon matrix upon the application of heat. Specifically, single crystal silicon samples, such as wafers, slugs or slabs, may be visually inspected for the presence of such defects by first coating a surface of the sample with a composition containing a metal capable of decorating these defects, such as a concentrated solution of copper nitrate. The coated sample is then heated to a temperature between about 900° C. and about 1000° C. for about 5 minutes to about 15 minutes in order to diffuse the metal into the sample. The heat-treated sample is then cooled to room temperature, thus causing the metal to become critically supersaturated and precipitate at sites within the sample matrix at which defects are present.

After cooling, the sample is first subjected to a non-defect delineating etch, in order to remove surface residue and precipitants, by treating the sample with a bright etch solution for about 8 to about 12 minutes. A typical bright etch solution comprises about 55 percent nitric acid (70% solution by weight), about 20 percent hydrofluoric acid (49% solution by weight), and about 25 percent hydrochloric acid (concentrated solution).

The sample is then rinsed with deionized water and subjected to a second etching step by immersing the sample in, or treating it with, a Secco or Wright etch solution for about 35 to about 55 minutes. Typically, the sample will be etched using a Secco etch solution comprising about a 1:2 ratio of 0.15 M potassium dichromate and hydrofluoric acid (49% solution by weight). This etching step acts to reveal, or delineate, agglomerated defects which may be present.

In an alternative embodiment of this “defect decoration” process, the single crystal silicon sample is subjected to a thermal anneal prior to the application of the metal-containing composition. Typically, the sample is heated to a temperature ranging from about 850° C. to about 950° C. for about 3 hours to about 5 hours. This embodiment is particularly preferred for purposes of detecting B-type silicon self-interstitial agglomerated defects. Without being held to a particular theory, it is generally believed that this thermal treatment acts to stabilize and grow B-defects, such that they may be more easily decorated and detected.

Agglomerated vacancy defects may also be detected using laser scattering techniques, such as laser scattering tomography, which typically have a lower defect density detection limit that other etching techniques.

In general, regions of interstitial and vacancy dominated material free of agglomerated defects can be distinguished from each other and from material containing agglomerated defects by the copper decoration technique described above. Regions of defect-free interstitial dominated material contain no decorated features revealed by the etching whereas regions of defect-free vacancy dominated material (prior to a high-temperature oxygen nuclei dissolution treatment as described above) contain small etch pits due to copper decoration of the oxygen nuclei.

Definitions

As used herein, the following phrases or terms shall have the given meanings: “agglomerated intrinsic point defects” or simply “agglomerated defects” mean defects caused (i) by the reaction in which vacancies agglomerate to produce D-defects, flow pattern defects, gate oxide integrity defects, crystal originated particle defects, crystal originated light point defects, and other such vacancy related defects, or (ii) by the reaction in which self-interstitials agglomerate to produce A-defects (including dislocation loops and networks) and B-defects, “B-defects” referring to agglomerated interstitial defects which are smaller than A-defect and which are capable of being dissolved if subjected to a thermal treatment (e.g., heating at about 1100° C. or more for several seconds or several tens of second), provided they have not first been thermally stabilized as described in, for example, U.S. Pat. No. 6,391,662 (which is incorporated herein by reference); “agglomerated interstitial defects” shall mean agglomerated intrinsic point defects caused by the reaction in which silicon self-interstitial atoms agglomerate; “agglomerated vacancy defects” shall mean agglomerated vacancy point defects caused by the reaction in which crystal lattice vacancies agglomerate; “radius” means the distance measured from a central axis to a circumferential edge of a wafer or ingot; “substantially free of agglomerated intrinsic point defects” shall mean a concentration (or size) of agglomerated defects which is less than the detection limit of these defects, which is currently about 10³ defects/cm³; “V/I boundary” means the position along the radius (or axis) of an ingot or wafer at which the material changes from vacancy dominated to self-interstitial dominated; “vacancy dominated” and “self-interstitial dominated” mean material in which the intrinsic point defects are predominantly vacancies or self-interstitials, respectively; “main body” generally refers to the substantially constant diameter portion of the ingot (the diameter typically varying, for example, by about 0.1%, 0.5%, 1% or more, depending upon the quality constraints and process control capabilities); and, “substantially constant,” as well as variations thereof (e.g., “generally constant,” etc.), typically refers to a given value (e.g., pull or growth rate, rotation rate, etc.) varying by less than about 5% (e.g., 3%, 1%, 0.5%, 0.1%) over the given duration (e.g., time, axial length, etc.).

In view of the foregoing, it can be seen that the desired type of silicon material can be established much earlier in the main body growth process by means of controlling the parameters affecting taper growth with this in mind.

As various changes could be made in the above processes without departing from the scope of the present invention, it is intended that all matter contained in the above description be interpreted as illustrative and not in a limiting sense.

What is claimed is:

1. A single crystal silicon ingot having a central axis, a crown, an end opposite the crown, and a main body between the crown and the opposite end having a lateral surface and a radius R extending from the central axis to the lateral surface which is at least about 75 mm, the ingot being characterized in that, after it is grown and cooled from the solidification temperature, the main body contains a region extending radially inward from the lateral surface which is axially symmetric about the central axis wherein silicon self-interstitials are the predominant intrinsic point defect, the axially symmetric region having an average radial width, as measured from the lateral surface toward the central axis, which is at least about 0.3R within about the first 10% of the main body.

2. The ingot of claim 1 wherein the radius is at least about 100 mm.

3. The ingot of claim 1 wherein the radius is at least about 150 mm.

4. The ingot of claim 1 wherein the axially symmetric region is present within about the first 6% of the main body.

5. The ingot of claim 1 wherein the axially symmetric region is present within about the first 2% of the main body.

6. The ingot of claim 1 wherein the axially symmetric region has an average radial width which is at least about 0.6R.

7. The ingot of claim 5 wherein the axially symmetric region is present within about the first 6% of the main body.

8. The ingot of claim 5 wherein the axially symmetric region is present within about the first 2% of the main body.

9. The ingot of claim 5 wherein the radius is at least about 100 mm.

10. The ingot of claim 5 wherein the radius is at least about 150 mm.

11. The ingot of claim 1 wherein the axially symmetric region has an average radial width which is at least about 0.9R.

12. The ingot of claim 11 wherein the axially symmetric region is present within about the first 6% of the main body.

13. The ingot of claim 11 wherein the axially symmetric region is present within about the first 2% of the main body.

14. The ingot of claim 11 wherein the radius is at least about 100 mm.

15. The ingot of claim 11 wherein the radius is at least about 150 mm.

16. The ingot of claim 1, wherein said ingot is P-type.

17. The ingot of claim 1, wherein said ingot is P⁺-type.

18. The ingot of claim 1, wherein said ingot is N-type.

19. A single crystal silicon ingot having a central axis, a crown, an end opposite the crown, and a main body between the crown and the opposite end having a lateral surface and a radius R extending from the central axis to the lateral surface which is at least about 75 mm, the ingot being characterized in that, after it is grown and cooled from the solidification temperature, the main body contains a region extending radially inward from the lateral surface which is axially symmetric about the central axis wherein silicon self-interstitials are the predominant intrinsic point defect, the axially symmetric region having a radial width, as measured from the lateral surface toward the central axis, over about the first half of the main body of the ingot which varies by less than about 10%.

20. The ingot of claim 19 wherein the radius is at least about 100 mm.

21. The ingot of claim 19 wherein the radius is at least about 150 mm.

22. The ingot of claim 19 wherein the axially symmetric region has an average radial width which is at least about 0.4R.

23. The ingot of claim 19 wherein the axially symmetric region has an average radial width which is at least about 0.8R.

24. The ingot of claim 19 wherein the width of the axially symmetric region varies by less than about 6%.

25. The ingot of claim 24 wherein the radius is at least about 100 mm.

26. The ingot of claim 24 wherein the radius is at least about 150 mm.

27. The ingot of claim 24 wherein the axially symmetric region has an average radial width which is at least about 0.4R.

28. The ingot of claim 24 wherein the axially symmetric region has an average radial width which is at least about 0.8R.

29. The ingot of claim 19 wherein the width of the axially symmetric region varies by less than about 2%.

30. The ingot of claim 29 wherein the radius is at least about 100 mm.

31. The ingot of claim 29 wherein the radius is at least about 150 mm.

32. The ingot of claim 29 wherein the axially symmetric region has an average radial width which is at least about 0.4R.

33. The ingot of claim 29 wherein the axially symmetric region has an average radial width which is at least about 0.8R.

34. The ingot of claim 19, wherein said ingot is P-type.

35. The ingot of claim 19, wherein said ingot is P⁺-type.

36. The ingot of claim 19, wherein said ingot is N-type.

37. A process for preparing a single crystal silicon ingot having a central axis, a crown, an end opposite the crown, and a main body between the crown and the opposite end which has a lateral surface and a radius extending from the central axis to the lateral surface which is at least about 75 mm, the process comprising:
heating polycrystalline silicon in a crucible to form a silicon melt;
contacting a seed crystal and the melt;
withdrawing the seed crystal from the melt to grow a neck portion adjacent the seed crystal;
growing an outwardly flaring crown adjacent the neck; and,
growing a main body adjacent the outwardly flaring crown, about the first 10% of said main body containing a region extending radially inward from the lateral surface which is axially symmetric about the central axis and wherein silicon self-interstitials are the predominant intrinsic point defect, the axially symmetric region having an average radial width, as measured from the lateral surface toward the central axis, which is at least about 0.3R.

38. The process of claim 37 wherein the radius is at least about 100 mm.

39. The process of claim 37 wherein the radius is at least about 150 mm.

40. The process of claim 37 wherein the axially symmetric region is present within about the first 6% of the main body.

41. The process of claim 37 wherein the axially symmetric region is present within about the first 2% of the main body.

42. The process of claim 37 wherein the axially symmetric region has an average radial width which is at least about 0.6R.

43. The process of claim 37 wherein the axially symmetric region has an average radial width which is at least about 0.9R.

44. The process of claim 37 wherein said axially symmetric region is formed in said main body by controlling growth of the crown.

45. The process of claim 44 wherein said controlled crown growth is achieved by increasing a pull rate by at least about 10% relative to a pull rate used for growing the neck, wherein said increase occurs prior to initiating growth of the main body.

46. The process of claim 45 wherein said pull rate is increased during formation of the first about 25% of the crown.

47. The process of claim 44 wherein said controlled crown growth is achieved by increasing a pull rate by at least about 30% relative to a pull rate used for growing the neck, wherein said increase occurs prior to initiating growth of the main body.

48. The process of claim 47 wherein said pull rate is increased during formation of the first about 25% of the crown.

49. The process of claim 44 wherein a pull rate during crown growth is decreased substantially linearly, said controlled crown growth being achieved by controlling (i) controlling heater power and (ii) crucible and seed crystal rotation rates.

50. A process for preparing a single crystal silicon ingot having a central axis, a crown, an end opposite the crown, and a main body between the crown and the opposite end which has a lateral surface and a radius extending from the central axis to the lateral surface which is at least about 75 mm, the process comprising:
heating polycrystalline silicon in a crucible to form a silicon melt;
contacting a seed crystal and the melt;
withdrawing the seed crystal from the melt to grow a neck portion adjacent the seed crystal;
growing an outwardly flaring crown adjacent the neck; and,
growing a main body adjacent the outwardly flaring crown which contains a region extending radially inward from the lateral surface which is axially symmetric about the central axis wherein silicon self-interstitials are the predominant intrinsic point defect, the axially symmetric region having a radial width, as measured from the lateral surface toward the central axis, over about the first half of the main body of the ingot which varies by less than about 10%.

51. The process of claim 50 wherein the radius is at least about 100 mm.

52. The process of claim 50 wherein the radius is at least about 150 mm.

53. The process of claim 50 wherein the axially symmetric region has an average radial width which is at least about 0.4R.

54. The process of claim 50 wherein the axially symmetric region has an average radial width which is at least about 0.8R.

55. The process of claim 50 wherein the width of the axially symmetric region varies by less than about 6%.

56. The process of claim 50 wherein the width of the axially symmetric region varies by less than about 2%.

57. The process of claim 50 wherein said axially symmetric region is formed in said main body by controlling growth of the crown.

58. The process of claim 57 wherein said controlled crown growth is achieved by increasing a pull rate by at least about 10% relative to a pull rate used for growing the neck, wherein said increase occurs prior to initiating growth of the main body.

59. The process of claim 58 wherein said pull rate is increased during formation of the first about 25% of the crown.

60. The process of claim 57 wherein said controlled crown growth is achieved by increasing a pull rate by at least about 30% relative to a pull rate used for growing the neck, wherein said increase occurs prior to initiating growth of the main body.

61. The process of claim 60 wherein said pull rate is increased during formation of the first about 25% of the crown.

62. The process of claim 57 wherein a pull rate during crown growth is decreased substantially linearly, said controlled crown growth being achieved by controlling (i) controlling heater power and (ii) crucible and seed crystal rotation rates.

63. A process for preparing a single crystal silicon ingot in which the ingot comprises a central axis, a crown, an end opposite the crown, and a main body between the crown and the opposite end having a lateral surface and a radius extending from the central axis to the lateral surface which is at least about 75 mm, the ingot being grown and then cooled from the solidification temperature in accordance with the Czochralski method wherein a seed crystal is lowered into contact with a silicon melt contained within a crucible and then withdrawn, the process comprising:
growing at least a first segment of the main body of the ingot at a substantially constant pull rate, the pull rate varying by less than about 10% over the axial length of said segment, wherein said segment (i) has an axial length which is at least about 25% of the main body axial length, and (ii) contains a region extending radially inward from the lateral surface which is axially symmetric about the central axis wherein silicon self-interstitials are the predominant intrinsic point defect.

64. The process of claim 63 wherein the radius is at least about 100 mm.

65. The process of claim 63 wherein the radius is at least about 150 mm.

66. The process of claim 63 wherein the first segment has an axial length of at least about the first 50% of the axial length of the main body.

67. The process of claim 63 wherein the pull rate varies by less than about 8% over the axial length of the first segment.

68. The process of claim 67 wherein the first segment has an axial length of at least about the first 50% of the axial length of the main body.

69. The process of claim 63 wherein the pull rate varies by less than about 4% over the axial length of the first segment.

70. The process of claim 67 wherein the first segment has an axial length of at least about the first 50% of the axial length of the main body.
